(19) United States
(12) Patent Application Publication
(10) Pub. No.: US 2013/0136850 A1
(43) Pub. Date: May 30, 2013

(54) METHOD FOR DEPOSITING MATERIALS ON A SUBSTRATE

(71) Applicants: Dennis G. Doyle, Shrewsbury, MA (US); Thomas C. Prentice, Westford, MA (US); Patsy A. Mattero, Smithfield, RI (US); David P. Prince, Wakefield, RI (US)

(72) Inventors: Dennis G. Doyle, Shrewsbury, MA (US); Thomas C. Prentice, Westford, MA (US); Patsy A. Mattero, Smithfield, RI (US); David P. Prince, Wakefield, RI (US)

(73) Assignee: Illinois Tool Works Inc., Glenview, IL (US)

(21) Appl. No.: 13/306,130

(22) Filed: Nov. 29, 2011

(51) Int. Cl. C23C 16/52

(52) U.S. Cl. 427/8; 427/58

(57) ABSTRACT

A method of depositing materials on an electronic substrate with a material deposition system is disclosed. The deposition system includes a frame, a gantry system coupled to the frame, a deposition head coupled to the gantry system and configured to deposit dots of low viscous and semi-viscous material on the electronic substrate, and a controller configured to control the operation of the material deposition system, including the operation of the gantry system and the deposition head. The method includes depositing a line or a pattern of material on the electronic substrate by moving the deposition head along an axis of motion that is substantially non-parallel to a direction of the line or pattern. Other methods and deposition systems are further disclosed.

### BACKGROUND OF THE INVENTION

1. Field of the Disclosure This disclosure relates generally to systems and methods for depositing a low viscous or semi-viscous material on a substrate, such as a printed circuit board, and more particularly to an apparatus and a method for depositing less viscous materials, such as electronic inks, on electronic substrates.

2. Discussion of Related Art

There are several types of prior art application systems used for dispensing or otherwise applying precise amounts of liquid or paste for a variety of applications. One such application is the assembly of integrated circuit chips and other electronic components onto circuit board substrates. In one embodiment of this application, automated dispensing systems are used for dispensing very small amounts, or dots, of viscous or semi-viscous materials onto a circuit board. The viscous materials may include liquid epoxy or solder paste, or some other related material. In a certain embodiment, the dispensing system may include an auger-type dispenser. In other embodiments, the dispensing system may include a jetter-type dispenser. In another embodiment of the application, material is applied onto the electronic substrate through a stencil of a stencil printer.

### BRIEF SUMMARY OF THE INVENTION

One aspect of the disclosure is directed to a method of depositing materials on an electronic substrate with a material deposition system of the type comprising a frame, a gantry system coupled to the frame, a deposition head coupled to the gantry system and configured to deposit dots of low viscous and semi-viscous material on the electronic substrate, and a controller configured to control the operation of the material deposition system, including the operation of the gantry system and the deposition head. In one embodiment, the method comprises depositing a line or a pattern of material on the electronic substrate by moving the deposition head along an axis of motion that is substantially non-parallel to a direction of the line or pattern.

Embodiments of the method further may include capturing an image of the electronic substrate with an inspection system. The method further may include adding an ultraviolet dye to the material prior to depositing so that the material is visible to the inspection system having an ultraviolet light source when material is deposited in extremely small sizes. The inspection system may include two cameras secured on the deposition head, with a first camera being configured for large field of view and a second camera being configured for small field of view. The method further may include cooling material deposited on the electronic substrate. Cooling may be achieved with a cooling chuck. The method further may include controlling the environment within the material deposition system. Controlling the environment may include isolating an area within the material deposition system to perform a deposit operation. The method further may include cleaning at least one of the deposition head and the electronic substrate. Cleaning may be achieved by using one of ozone, CO₂, infrared lighting, ultraviolet lighting, plasma and organic solvent, such as IPA or ethanol. The method further may include surrounding the deposition head with a vaporous environment when static to prevent drying of material on the deposition head. Surrounding the deposition head may be achieved with a solvent. Depositing material on the electronic substrate may include advancing and retarding firing pulses of the deposition head to compensate for errors in the deposit process, including deposition head placement error, material trajectory error, and gantry system error. Depositing material on the electronic substrate further may include advancing and retarding firing pulses of the deposition head to compensate for misalignment or variations of the electronic substrate.

Another aspect of the disclosure is directed to a method of depositing materials on an electronic substrate with a material deposition system of the type comprising a frame, a gantry system coupled to the frame, a deposition head coupled to the gantry system and configured to deposit dots of low viscous and semi-viscous material on the electronic substrate, an inspection system configured to capture an image of the electronic substrate, and a controller configured to control the operation of the material deposition system, including the operation of the gantry system, the deposition head, and the inspection system. In one embodiment, the method comprises: capturing an image of the electronic substrate with the inspection system; generating a pattern of material to be deposited on the electronic substrate with the controller; and depositing a line or a pattern of material on the electronic substrate based on the pattern of material generated by the controller by moving the deposition head along an axis of motion that is substantially non-parallel to a direction of the line or pattern.

Embodiments of the method further may include adding an ultraviolet dye to the material prior to depositing so that the material is visible to the inspection system having an ultraviolet light source when material is deposited in extremely small sizes. The inspection system may include two cameras secured on the deposition head, a first camera being configured for large field of view and a second camera being configured for small field of view. The method further may include cooling material deposited on the electronic substrate. Cooling may be achieved with a cooling chuck. The method further may include controlling the environment within the material deposition system. Controlling the environment may include isolating an area within the material deposition system to perform a deposit operation. The method further may include cleaning at least one of the deposition head and the electronic substrate. Cleaning may be achieved by using one of ozone, CO₂, infrared lighting, ultraviolet lighting, plasma and organic solvent, such as IPA or ethanol. The method further may include surrounding the deposition head with a vaporous environment when static to prevent drying of material on the deposition head. Surrounding the deposition head may be achieved with a solvent. Depositing material on the electronic substrate may include advancing and retarding firing pulses of the deposition head to compensate for errors in the deposit process, including deposition head placement error, material trajectory error, and gantry system error. Depositing material on the electronic substrate further may include advancing and retarding firing pulses of the deposition head to compensate for misalignment or variations of the electronic substrate. The line or the pattern of material may be deposited by moving the deposition head along an axis of motion that is substantially non-parallel to a direction of the line or the pattern.

Another aspect of the disclosure is directed to a material deposition system for depositing material on an electronic substrate. In one embodiment, the material deposition system comprises a frame, a support assembly coupled to the frame, the support assembly being configured to support the electronic substrate, a gantry system movably coupled to the frame, a deposition head coupled to the gantry system, the deposition head being configured to deposit material, and a controller coupled to the gantry system and the deposition head. The controller is configured to manipulate the gantry system and the deposition head to deposit a line or a pattern of material on the electronic substrate by moving the deposition head along an axis of motion that is substantially non-parallel to a direction of the line or pattern.

Embodiments of the material deposition system further may include an inspection system configured to capture an image of the electronic substrate. The system further may include a material supply cartridge coupled to the deposition head. In one embodiment, ultraviolet dye is added to the material prior to depositing the material so that the material is visible to the inspection system having an ultraviolet light source when material is deposited in extremely small sizes. The system further may include a fan and at least one heater coupled to the deposition head. The fan and the at least one heater may be configured to reduce the viscosity of the material prior to being deposited on the electronic substrate. The support assembly may include a cleaning station configured to clean the deposition head. The cleaning station may include a paper wiper system configured to wipe the deposition head with paper. The cleaning station further may include a compliant pad positioned beneath the paper wiper system to conform to irregularities in the deposition head and paper of the paper wiper system. The controller may be configured to advance and retard firing pulses of the deposition head to compensate for errors in depositing.

Another aspect of the disclosure is directed to a material deposition system for depositing material on an electronic substrate. In one embodiment, the material deposition system comprises a frame, a support assembly coupled to the frame, the support assembly being configured to support the electronic substrate, a gantry system movably coupled to the frame, a deposition head coupled to the gantry system, the deposition head being configured to deposit material, and a controller coupled to the gantry system and the deposition head. The controller is configured to manipulate the gantry system and the deposition head to deposit material on the substrate. The deposition head includes a 2ⁿ drop nozzle, wherein n is 4 or greater.

Embodiments of the material deposition system further may further include an inspection system coupled to the deposition head. The inspection system may be configured to inspect material deposited on the electronic substrate. The system further may include a material supply cartridge coupled to the deposition head. In one embodiment, ultraviolet dye may be added to the material prior to depositing so that the material is visible to the inspection system having an ultraviolet light source when material is deposited in extremely small sizes. The system further may include a fan and at least one heater coupled to the deposition head. The fan and the at least one heater may be configured to reduce the viscosity of the material deposited on the electronic substrate. The support assembly may include a cleaning station configured to clean the deposition head. The cleaning station may include a paper wiper system configured to wipe the deposition head with paper. The cleaning station further may include a compliant pad positioned beneath the paper wiper system to conform to irregularities in the deposition head and paper of the paper wiper system. The controller may be configured to advance and retard firing pulses of the nozzle of the deposition head to compensate for errors in depositing material.

Another aspect of the disclosure is directed to a material deposition system for depositing material on an electronic substrate. In one embodiment, the material deposition system comprises a frame, a support assembly coupled to the frame, the support assembly being configured to support the electronic substrate, a gantry system movably coupled to the frame, a deposition head coupled to the gantry system, the deposition head being configured to deposit material, an imaging system configured to capture an image of the electronic substrate, and a controller coupled to the gantry system and the deposition head. The controller is configured to generate a pattern of material to be deposited on the electronic substrate based on at least one image captured by the imaging system. The controller further is configured to manipulate the gantry system and the deposition head to deposit a line or a pattern of material on the electronic substrate based on the pattern of material generated by the controller.

Embodiments of the material deposition system further may include configuring the controller to manipulate the gantry system and the deposition head to move the deposition head along an axis of motion that is substantially non-parallel to a direction of the line or pattern. The controller further may be configured to advance and retard firing pulses of the deposition head to compensate for errors in depositing. The deposition head may include a 2ⁿ drop nozzle, wherein n is 4 or greater.

Another aspect of the disclosure further may be directed to an inspection system configured for off axis viewing of dispensed materials so that the wet deposits are visible without ultraviolet or infrared lighting.

Another aspect of the disclosure further may include curing material dispensed on the electronic substrate. Curing may be achieved with one of a hot chuck, infrared light source, and an ultraviolet light source.

Another aspect of the disclosure further may include controlling the environment by isolating an area within the dispenser apparatus to perform a dispense operation.

Another aspect of the disclosure further may include removing air from a line of material supplying material to the dispensing head and/or removing air from a line of material includes using gravity.

Another aspect of the disclosure further may include controlling a temperature of at least one of a cartridge containing material, a fluid path supplying material from the cartridge to the dispensing head, and the dispensing head.

Another aspect of the disclosure further may include cleaning the dispensing head with a paper wiper system. Cleaning the dispensing head may include positioning a compliant pad beneath the paper wiper system to conform to irregularities in the dispensing head and paper of the paper wiper system.

Another aspect of the disclosure further may include implementing a drop watcher system with a secondary lens/window system that is removable from the dispenser apparatus to allow for easy cleaning.

Another aspect of the disclosure further may include detecting air within the dispensing head with bubble sensors.

Another aspect of the disclosure further may be directed to a dispensing head including a window through which material flowing through the dispensing head may be viewed.

### BRIEF DESCRIPTION OF THE DRAWINGS

The accompanying drawings are not intended to be drawn to scale. In the drawings, each identical or nearly identical component that is illustrated in various figures is represented by a like numeral. For purposes of clarity, not every component may be labeled in every drawing. In the drawings:

FIG. 1 is a side schematic view of a material deposition or application system;

FIG. 2 is a perspective view of an exemplary material deposition system embodying a gantry system and a material deposition head of an embodiment of the present disclosure;

FIG. 3 is a perspective view of the gantry system and the material deposition head shown in FIG. 2;

FIG. 4 is a perspective view of the gantry system and the material deposition head with parts removed to better illustrate components thereof;

FIG. 5 is a perspective view of a support assembly configured to support the material deposition head;

FIGS. 6-10 are perspective views of the material deposition head;

FIG. 11 is a perspective view of a peripheral station assembly of the material deposition system;

FIGS. 12-15 are perspective views of peripheral stations of the material deposition system;

FIGS. 16A-C are schematic views showing prior art methods of depositing lines of material; and

FIGS. 17A-C are schematic views showing various methods of depositing lines of material using a multi-nozzle print head of the present disclosure.

### DETAILED DESCRIPTION OF THE INVENTION

For the purposes of illustration only, and not to limit the generality, the present disclosure will now be described in detail with reference to the accompanying figures. This disclosure is not limited in its application to the details of construction and the arrangement of components set forth in the following description or illustrated in the drawings. The principles set forth in this disclosure are capable of other embodiments and of being practiced or carried out in various ways. Also the phraseology and terminology used herein is for the purpose of description and should not be regarded as limiting. The use of “including,” “comprising,” “having,” “containing,” “involving,” and variations thereof herein, is meant to encompass the items listed thereafter and equivalents thereof as well as additional items.

Various embodiments of the present disclosure are directed to material deposition or application systems, devices including such material deposition system, and methods of depositing material.

Specifically, the present disclosure is directed to a material deposition system including a machine base, a workholder (substrate fixture), a conveyor system (optional) for transporting the substrate, a deposition canister, and an x-axis, y-axis, and z-axis gantry for positioning the deposition canister over the substrate. The deposition canister includes, among other components, such as interface electronics, a material supply syringe, a pinch valve, a recirculation pump, a material reservoir with level sensor, a filter, tubing, multiple heating subsystems (for the material deposition canister and syringe), and a print head. The print head is an assembly that, in the preferred embodiment consists of a fluid inlet port, a fluid outlet port, multiple piezo driven fluid pumping chambers, a fluid delivery manifold that communicates fluid between the inlet, the outlet and the fluid pumping chambers, and an outlet nozzle for each of the multiple fluid pumping chambers. The print head has a monolithic nozzle plate, with a multitude of small openings, each of which forms a nozzle from which material may be ejected.

In one embodiment, the single print head includes a 2ⁿ drop nozzle, wherein n is 4 or greater. For example, the single print head may have 8, 16, 32, 64, 124 or 256 nozzles arranged in a single linear array. Other embodiments could include multiple material deposition heads. The fixed pattern nature of the nozzles of the print head relative to each other lends itself to non-parallel movement of the print head with respect to lines of a pattern to be deposited. If an array of lines were deposited by using one nozzle per line and by moving the print head along the direction of the lines, the resulting spacing between lines would be fixed by the nozzle-to-nozzle spacing and by the angle of the print head relative to the direction of travel. Thus, any imperfections in the spacing between the nozzles or in the rotation of the print head relative to a direction of travel would result in placement errors of the deposited lines. Each nozzle would deposit a single line.

If the nozzle is misplaced in the print head or misaligned in trajectory, then the resulting line would also be misplaced. Furthermore, the regular spacing of the nozzles of the print head dictates regularly spaced lines, or at least line spacing that is a multiple of the effective nozzle spacing. However, if the lines are deposited by moving the array of nozzles in a direction that is non-parallel to the line to be deposited, then each line may be constructed by a series of drops, each drop within a given line being contributed by a different nozzle. Accordingly, the location of the line to be drawn becomes a function of not only where each nozzle is located, but also when each nozzle is fired. The position of each line may thus be independently varied by varying the timing of the nozzles, as each of the nozzles in the print head pass over the desired locations of the lines to be deposited. Errors in the placement of each nozzle may be further calibrated, such that the timing of a given nozzle can compensate for errors in its placement. The drops may then be placed along the intended lines to be deposited to an accuracy better than that built into the print head at the time of manufacture.

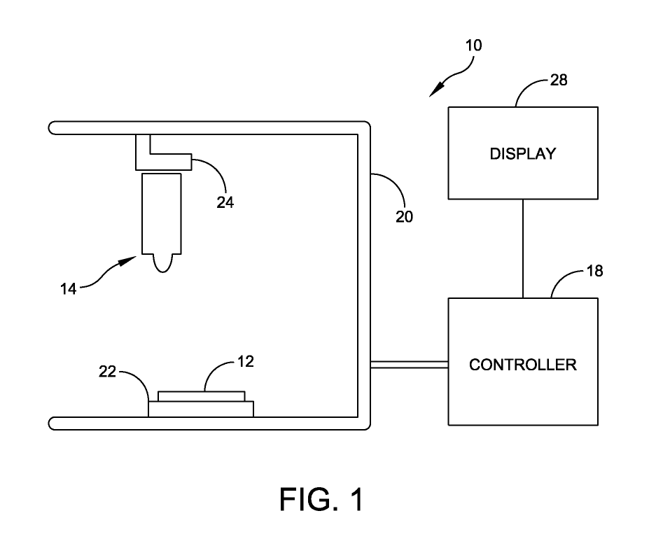

FIG. 1 schematically illustrates a material deposition system, generally indicated at 10, according to one embodiment of the present disclosure. The material deposition system 10 is used to deposit low viscous materials (e.g., materials having less than fifty centipoise) onto an electronic substrate 12, such as a printed circuit board or semiconductor wafer. Electronic substrate 12 further may include other substrates, such as solar cells. The material deposition system 10 may also be used to deposit other less viscous materials (semi-viscous materials), such as conductive inks, onto the electronic substrate 12. The material deposition system 10 may alternatively be used in other applications, such as for applying automotive gasketing material or in certain medical applications. It should be understood that references to low viscous or semi-viscous materials, as used herein, are exemplary and unless otherwise specified intended to be non-limiting.

The material deposition system 10 includes a deposition unit or head, generally indicated at 14, and a controller 18 to control the operation of the material deposition system. Although a single deposition head is shown, it should be understood that two or more deposition heads may be provided. The material deposition system 10 may also include a frame 20 having a base 22 for supporting the substrate 12, and a gantry system 24 movably coupled to the frame 20 for supporting and moving the deposition head 14. The deposition head 14 and the gantry system 24 are coupled to the controller 18 and operate under the direction of the controller. A conveyor system (not shown) or other transfer mechanism, such as a walking beam, may be used in the material deposition system 10 to control loading and unloading of circuit boards to and from the material deposition system. The gantry system 24 can be moved using motors under the control of the controller 18 to position the deposition unit 14 at predetermined locations over the circuit board. The material deposition system 10 may optionally include a display unit 28 connected to the controller 18 for displaying various information to a user. In another embodiment, there may be an optional second controller for controlling the deposition unit.

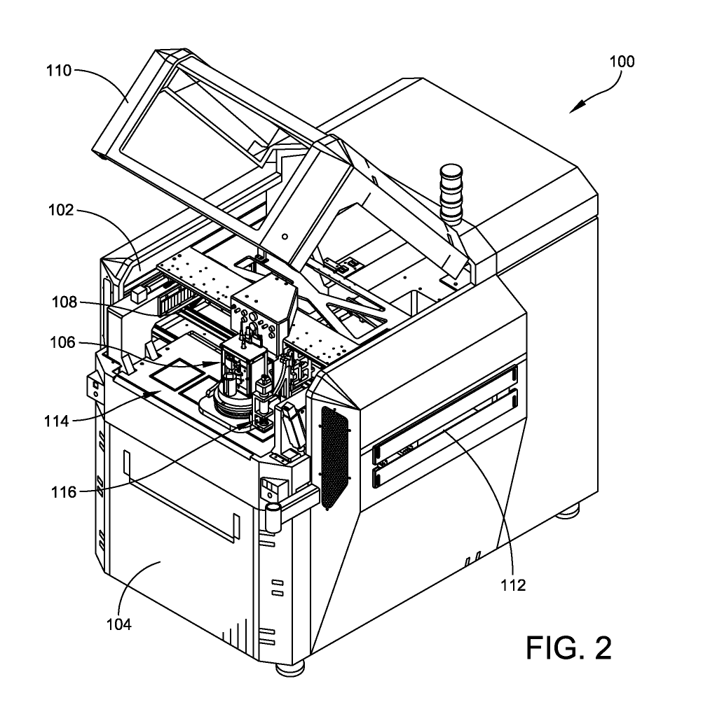

Referring to FIG. 2, an exemplary material deposition system, generally indicated at 100, may be configured from a XYFLEXPRO® dispenser platform offered by Speedline Technologies, Inc. of Franklin, Mass. The material deposition system 100 includes a frame 102 that supports components of the material deposition system, including but not limited to a controller, such as controller 18, which is located in a cabinet 104 of the material deposition system, and a deposition head, generally indicated at 106, for depositing low viscous and/or semi-viscous materials. The deposition head 106 may be movable along orthogonal axes by a gantry system, generally indicated at 108, under the control of the controller 18 to allow dispensing of the material on the circuit board, such as substrate 12, which, as mentioned above, may sometimes be referred to as an electronic substrate or a circuit board. A cover 110 is shown in an open position to reveal the internal components of the material deposition system 100, including the deposition head 106 and the gantry system 108.

Circuit boards, such as substrates 12, that are fed into the material deposition system, typically have a pattern of pads or other, usually conductive surface areas onto which material will be deposited. The material deposition system 100 also includes a conveyor system (not shown) that is accessible through an opening 112 provided along each side of the material deposition system to transport the circuit board in an x-axis direction to a depositing position in the material deposition system. In some implementations, the material deposition system 100 has a peripheral station assembly, generally indicated at 114, positioned adjacent to the circuit board when the circuit board is in the depositing position under the deposition head 106. When directed by the controller of the material deposition system 100, the conveyor system supplies circuit boards to a location adjacent to the peripheral station assembly 114 and under the deposition head 106. Once arriving at the position under the deposition head 106, the circuit board is in place for a manufacturing operation, e.g., a deposition operation.

The material deposition system 100 further includes a vision inspection system, generally indicated at 116, that is configured to align the circuit board and to and inspect the material deposited on the circuit board. To successfully deposit material on the circuit board, the circuit board and the deposition head 106 are aligned, via the controller. Alignment is accomplished by moving the deposition head 106 and/or the circuit board based on readings from the vision inspection system 116. When the deposition head 106 and the circuit board are aligned correctly, the deposition head is manipulated to perform a deposition operation. After the deposition operation, optional inspection of the circuit board by means of the vision inspection system 116 may be performed to ensure that the proper amount of material has been deposited and that the material has been deposited at the proper locations on the circuit board. The vision inspection system 116 can use fiducials, chips, board apertures, chip edges, or other recognizable patterns on the circuit board to determine proper alignment. After inspection of the circuit board, the controller controls movement of the circuit board to the next location using the conveyor system, where a next operation in the board assembly process may be performed, for example electrical components may be placed on the circuit board or the materials deposited on the board may be cured.

In some embodiments, the material deposition system 100 may operate as follows. The circuit board may be loaded into the material deposition system 100 in a depositing position using the conveyor system and by aligning the circuit board with the deposition head 106. The deposition head 106 may then be initiated by the controller to perform a deposit operation in which material is deposited at precise locations on the circuit board. Once the deposition head 106 has performed a depositing operation, the circuit board may be transported by the conveyor system from the material deposition system 100 so that a second, subsequent circuit board may be loaded into the material deposition system.

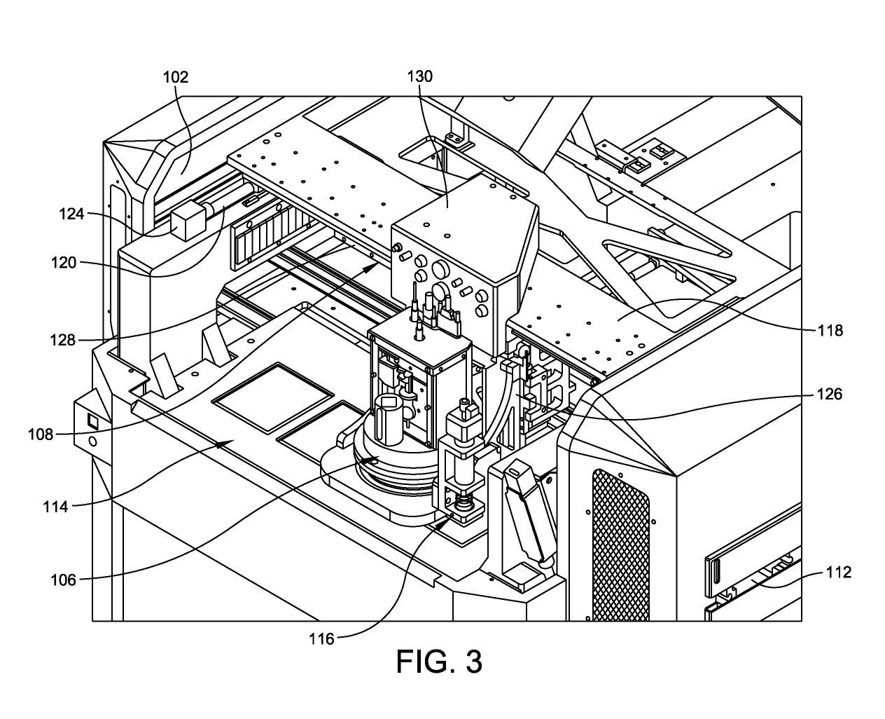

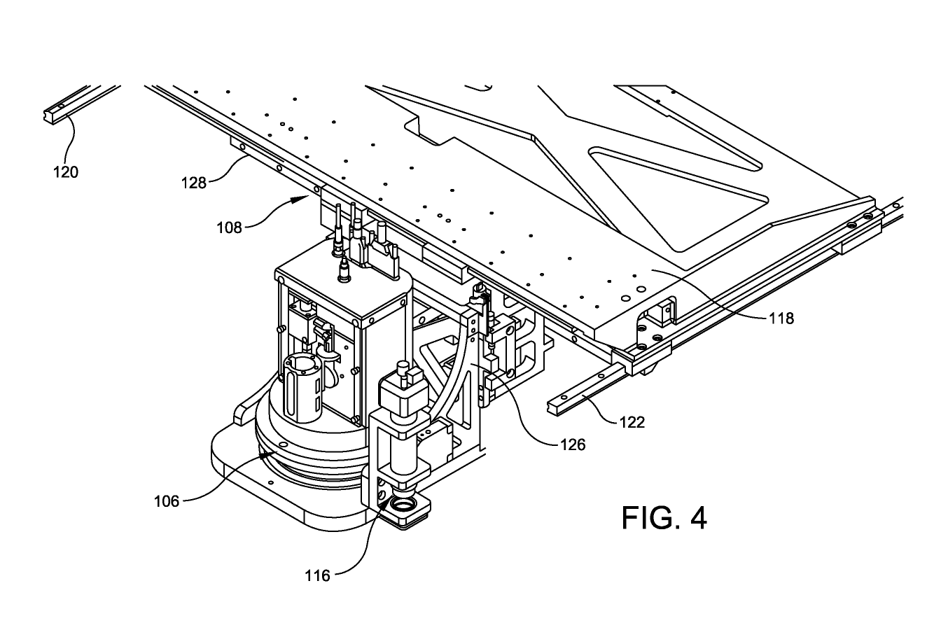

FIGS. 3 and 4 illustrate the deposition head that is movable in x-axis and y-axis directions by the gantry system 108. In one embodiment, the gantry system 108 includes a gantry platform 118 that rides along a pair of spaced-apart rails 120, 122 provided along opposite sides of the material deposition system to provide movement of the gantry platform in the y-axis direction. The gantry platform 118 is configured to be driven by any suitable movement mechanism, such as a ball screw, a pulley, or a belt drive mechanism, which is powered by a suitable motor. The preferred embodiment incorporates linear brushless motors for this purpose. Stops 124 are provided at the ends of the rails 120, 122 to limit the movement of the gantry platform 118 in the y-axis direction. The deposition head 106 is secured to a support structure 126, which in turn is configured to ride along a linear bearing 128 that is secured to an underside of the gantry platform 118 in an x-axis direction. The arrangement is that the deposition head 106 is capable of moving along x-axis direction. An electronics interface box 130 provides communication and/or power from the controller to the deposition head 106.

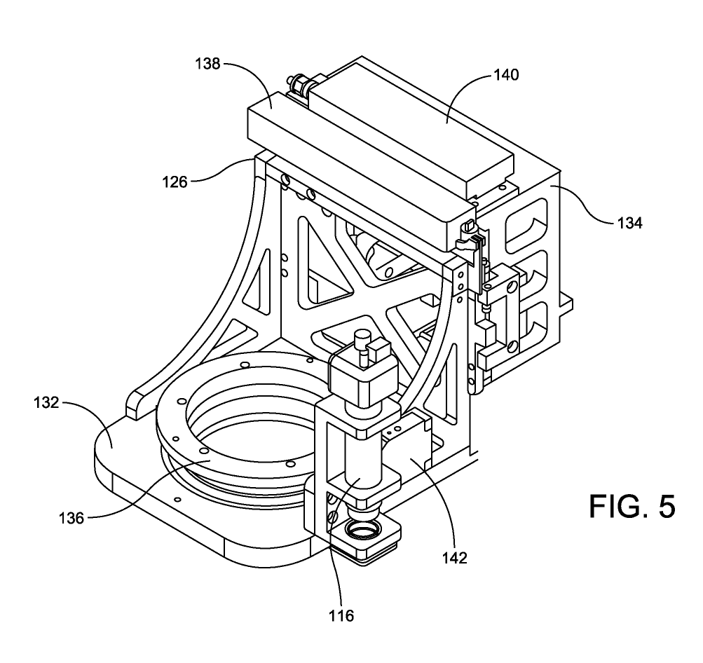

Referring to FIG. 5, the support structure 126 includes a mount assembly 132 and a gantry mount assembly 134. The mount assembly 132 includes one or more mount rings 136 that are used to secure the deposition head 106 to the support structure 126 in the manner described in greater detail below. The gantry mount assembly 134 includes a bracket 138 configured to ride along the linear bearing 128. A motor 140 is provided to drive the movement of the support structure 126 (and the deposition head 106) along the linear bearing 128. The support structure 126 further supports the vision inspection system 116, which may be configured to include one or more cameras that are designed to view the electronic substrate and/or locations within the peripheral station assembly 114. The support structure further houses a laser height sensor 142 that is designed to measure a height of the deposition head 106 from the electronic substrate and/or the peripheral station assembly 114. The vision inspection system 116 and the laser height sensor 142 are suitably coupled to the mount assembly 132 of the support structure 126 and to the controller.

The support structure 126 is configured to provide z-axis movement of the deposition head 106 toward and away from the circuit board. Specifically, the mount assembly 132 is configured to move along a z-axis direction with respect to the gantry mount assembly 134 by a motor (not shown) under the control of the controller. The laser height sensor 142 may be used to measure a distance of the deposition head 106 from the substrate or the peripheral station assembly 114. In another embodiment, the system includes a theta axis (rotation in the X-Y plane) to adjust the angle of a print head of the material deposition head.

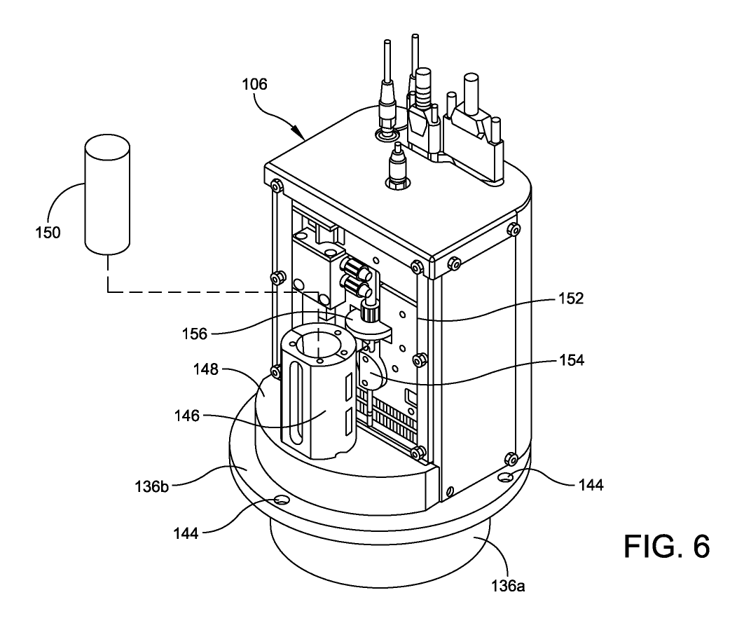

Turning now to FIGS. 6-10, and in particular FIG. 6, the deposition head 106 includes a cylindrical body 136a having a flange 136b that is mounted within and secured to the mount ring 136, which in turn is secured to the support structure 126 (not shown in FIG. 6). The deposition head 106 may be secured to the mount ring 136 by a bayonet-type twist mount and a dowel pin (not shown). The flange 136b of the deposition head 106 has multiple openings 144 each configured to receive a suitable fastener (not shown), e.g., a machine screw, to secure the flange to the mount ring 136. The arrangement is such that the deposition head 106 can rotate relative to the support structure 126 a predetermined degree of rotation. A cartridge support 146 is secured to a housing 148 the deposition head 106, the cartridge support being configured to receive a generally cylindrical material supply cartridge 150 to provide material (e.g., conductive ink) to the deposition head. Heaters (not designated) may be provided to heat the material being deposited. A pane or window of glass 152, or suitable transparent material, may be provided to view the flow of material through the deposition head 106.

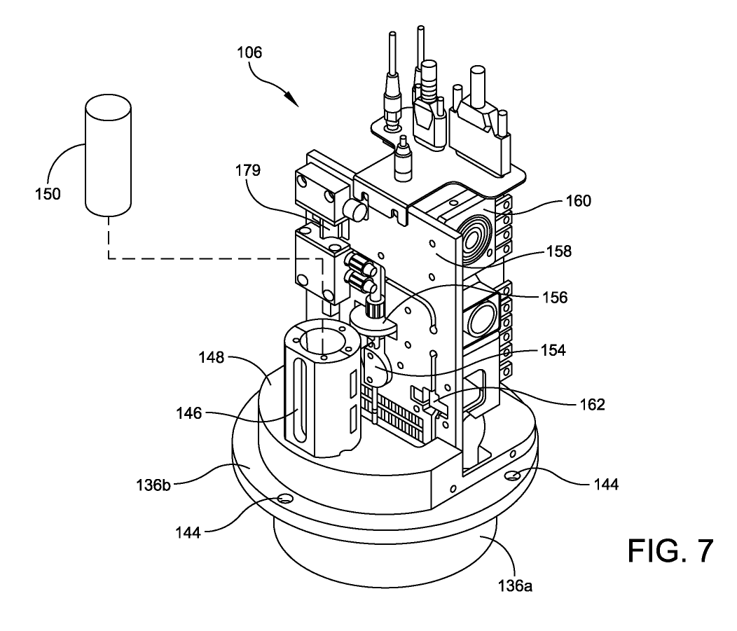

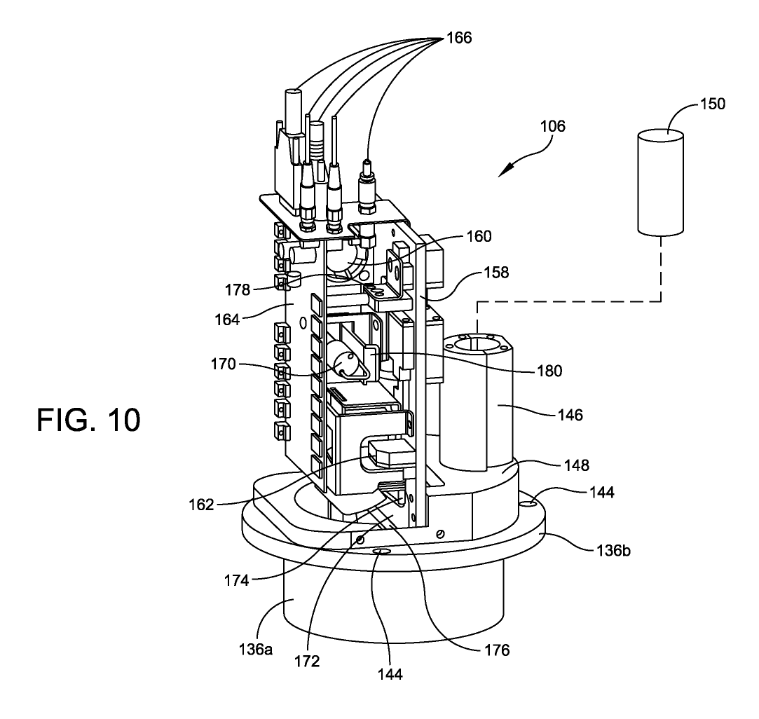

In FIG. 7, material flows from the cartridge 150 through a pinch valve 154 and a filter 156. A plate 158 maintains material in a thermally stable environment as the material is being deposited. A fan 160 is provided to circulate air within the deposition head to assist in achieving a consistent temperature (e.g., sixty-five degrees Celsius) in the deposition head 106. Bubble sensors 162 (refer also to FIG. 10) may be provided into and/or out of the deposition head 106 so that the controller can monitor the flow of material and whether air is present within the flow of material. Material can be re-circulated within the deposition head 106 until air is removed from the material flow path.

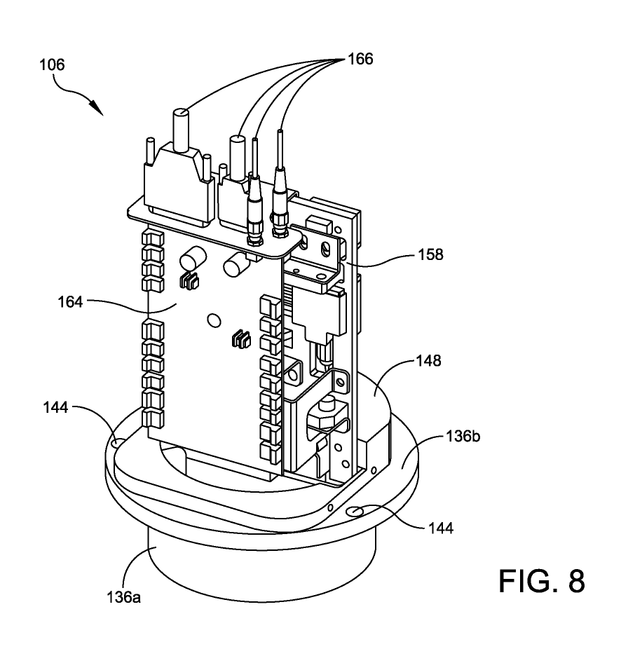

In FIG. 8, the deposition head 106 includes a control board 164 that controls the operation of the various components of the deposition head. The deposition head 106 communicates with the controller and other components of the material deposition system 100 by way of cables, each indicated at 166.

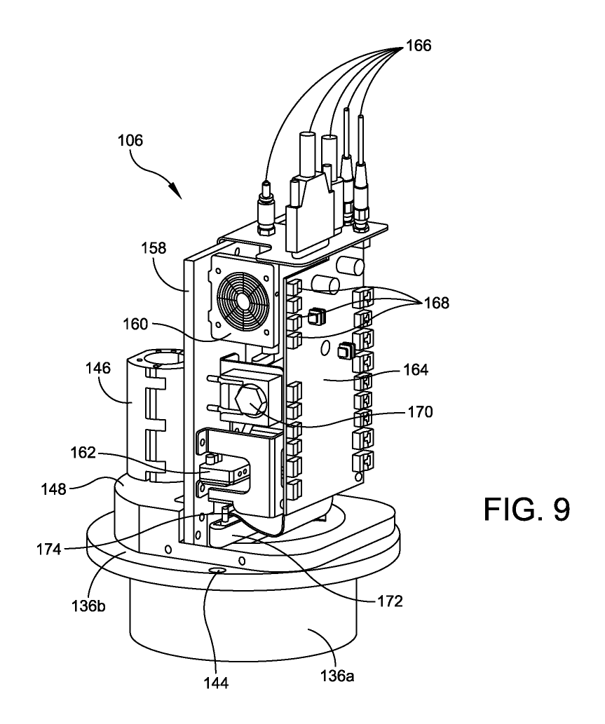

In FIG. 9, the fan 160 is clearly illustrated. Several heating elements, each indicated at 168, may be provided to heat the air circulated by the fan 160. The bubble sensor 162 is also clearly illustrated. The deposition head 106 includes a recirculation pump 170 to drive the movement of material through the deposition head. A jetting assembly 172, configured to deposit material, such as conductive ink, is connected to the housing 148 of the deposition head 106 by a connector 174. In one embodiment, the jetting assembly 172 includes a nozzle plate, which, in a certain embodiment, may be a 2ⁿ drop nozzle, wherein n is 4 or greater. For example, the jetting assembly 172 may be Q-class 256 nozzle drop-on-demand jetting assembly provided by FUJIFILM Dimatix, Inc. of Santa Clara, Calif.

In FIG. 10, in one embodiment, one bubble sensor 162 may be positioned within the flow of material prior to being delivered from the cartridge 150 to the deposition head 106 and another bubble sensor may be positioned within the flow of material in the deposition head. In another embodiment, a sensor may be provided in a line leading to the deposition head 106 or in a line exiting from the dispensing head. A heated manifold 176 may be further provided to heat the material and to communicate the heated material to and from the jetting assembly 172. A sensor 178 is provided to measure the level of material within a reservoir 179 provided within the deposition head. The reservoir 179 (FIG. 7) consists of a short piece of clear tubing (e.g., ½-inch diameter tubing) and two blocks that connect to the tubing and sealed by o-rings. The two blocks form caps and provide fitting locations where fluid and/or air can be communicated to the reservoir 179. The sensor 178 is designed to look through the clear tube of the reservoir 179 to view whether fluid in the tube is above or below a predetermined level. The pump 170, which may include a circuit board to control the operation of the pump, is mounted on a pump mount 180.

In a certain embodiment, the material supplied from the material supply cartridge is used to refill the reservoir. When the sensor 178 detects that the level in the reservoir has dropped, the controller opens the pinch valve 154, and permits additional material to flow into the reservoir from the cartridge 150. When the sensor 178 detects that the level has exceeded the level set by the sensor, the pinch valve 154 is closed. The level is thus maintained at a substantially constant level, with variations in the level limited by the hysteresis of the sensor 178 and the response time of the sensor, controller (e.g., controller 18) and the pinch valve 154. The level of the material in the reservoir, along with the density of the material, establishes a generally constant head pressure of the fluid at a nozzle faceplate. Under normal conditions, since each nozzle of the jetting assembly 172 provides an open fluid path, this head pressure would cause the fluid to run out of the nozzles. To compensate for this head pressure, a precision vacuum regulator (not shown) is connected to the air space above the material in the reservoir. The vacuum level is set to maintain, typically, a slightly net negative fluid pressure at the nozzles. The surface tension of the fluid, in balance with the slightly net negative fluid pressure, maintains a fluid meniscus at each nozzle opening. If the meniscus vacuum is set too low, the fluid drips out. If it is set too high, then air may be ingested back into the print head, and the nozzle will become un-primed. To effect a purge operation (pushing material out of the nozzles), the meniscus vacuum level is raised to a slightly positive pressure, typically a few PSI. As the material is pushed out of the nozzles, the level in the reservoir starts to drop, the sensor 178 causes the pinch valve 154 to open, and the pressurized fluid in the syringe refills the reservoir. When the purge pressure returns to the controlled meniscus vacuum level, the system returns to a state of equilibrium with the material forming a meniscus at each nozzle.

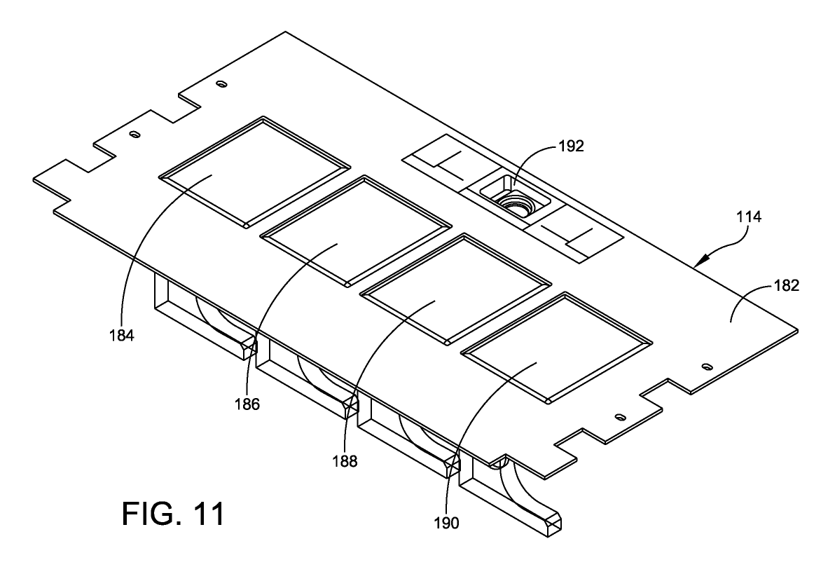

Turning now to FIG. 11, the peripheral station assembly 114 is shown apart from the other components of the material deposition system 100. As shown, the peripheral station assembly 114 includes a drop shield 182, having openings for four stations 184, 186, 188, 190 and a viewing station 192. The peripheral station assembly is located within the material deposition system such that the peripheral stations may be accessed by the deposition head 106. As shown, the four stations include a wiper station 184 configured to clean the nozzle plate of the jetting assembly 172 of the deposition head 106, a capping station 188, and a purge cup station 190. It should be understood that these stations 184, 186, 188, 190 may be arranged in any manner on the support platen 182, and that other types of stations to perform other functions may be further included or replace one of the stations described herein. The viewing station 192 is provided to view the deposition of material from the nozzles.

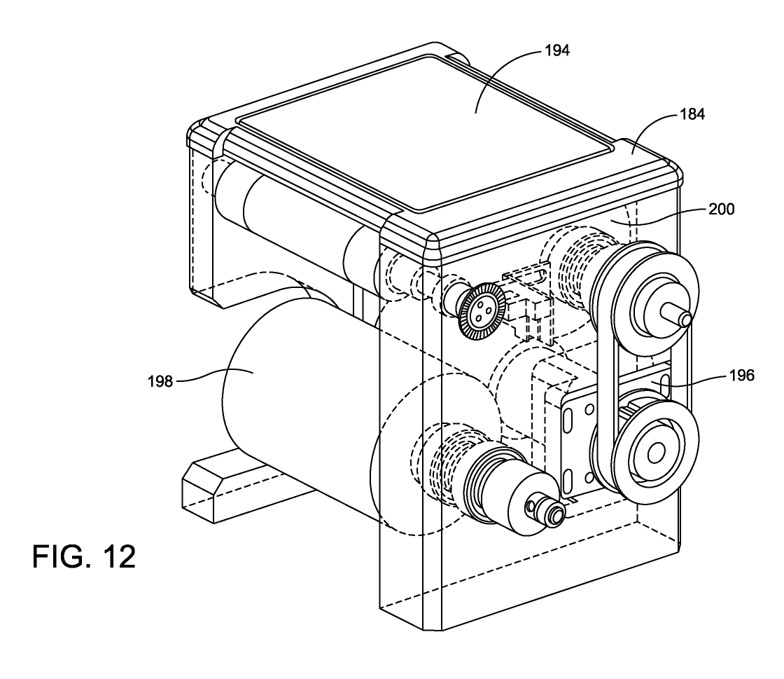

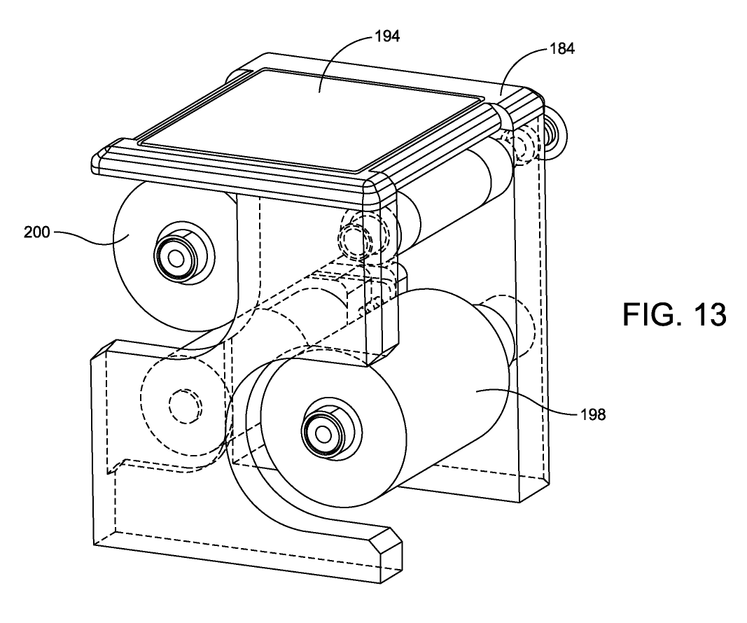

FIGS. 12 and 13 illustrate one embodiment of the wiper station 184. As shown, compliant material, such as a silicone pad 194, is provided under a paper supply (the paper being removed from FIGS. 12 and 13 to better illustrate the components of the wiper station 184. The paper (not shown) is provided to wipe the nozzle plate of the jetting assembly 172 of the deposition head 106. A suitable mechanism (e.g., a motor 196) is provided to drive the movement of the paper from a supply roll 198 to a take-up roll 200. The arrangement is such that the nozzle plate of the jetting assembly 172 of the deposition head 106 is cleaned by lowering the nozzle via the support structure 126 and moving the deposition head across the paper to clean the nozzle. Alternatively, the paper could be moved while the nozzle plate is in contact with the paper. The compliant material 194 ensures that the paper gently wipes the nozzle plate of the jetting assembly 172 during this process.

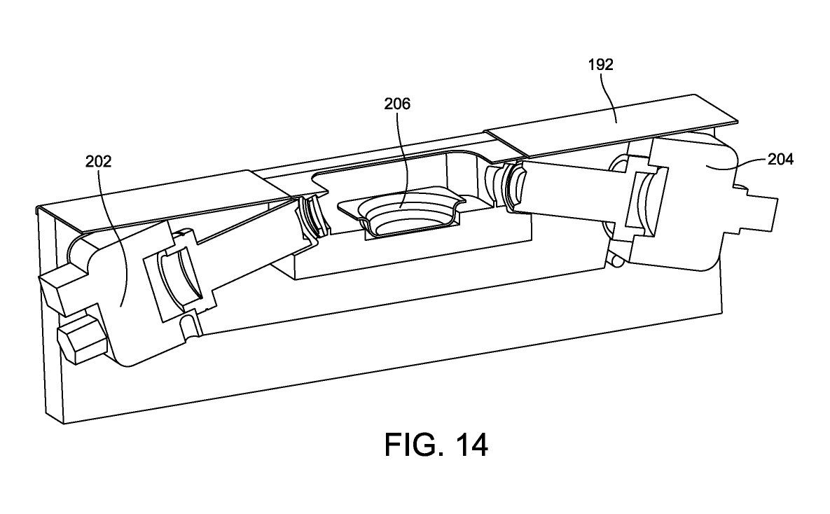

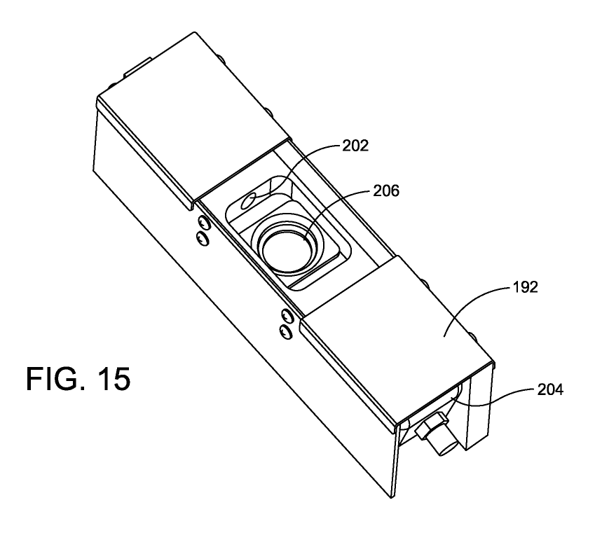

FIGS. 14 and 15 illustrate one embodiment of the viewing station 192. As shown, the viewing station consists of an LED strobe light 202 configured to direct light toward the deposition operation and a camera 204 configured to receive images of the deposition operation. A catch basin 206 is provided to capture material deposited.

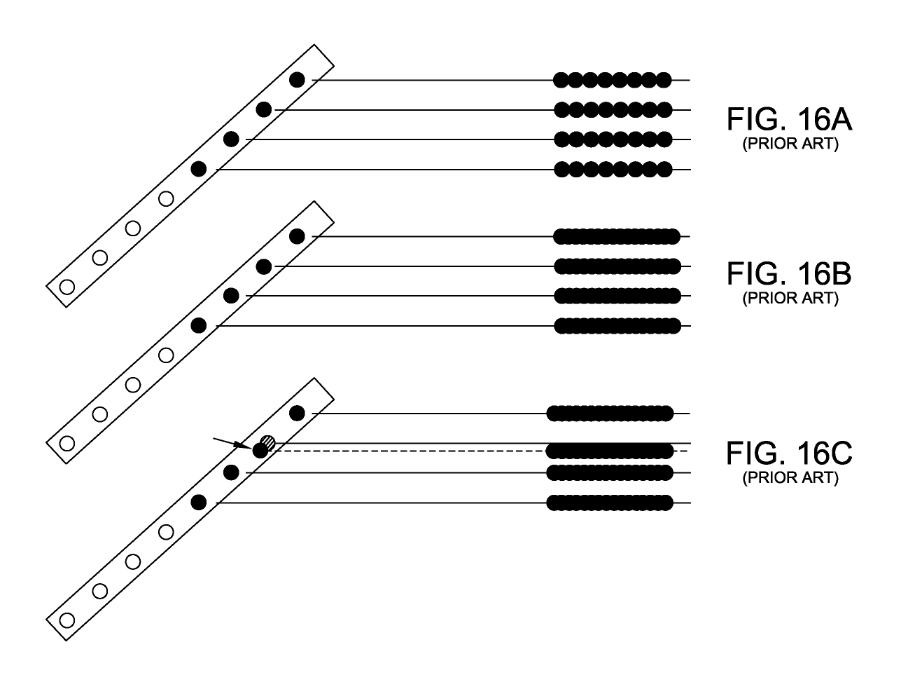

The material deposition system discussed with reference to FIGS. 2-15 is capable of performing many methods of depositing low viscous and semi-viscous materials onto an electronic substrate. For example, when depositing lines or patterns of material, one method may embody moving the deposition head along an axis of motion that is generally perpendicular to a direction of the line or pattern. Thus, the deposition head is moved in a direction that is generally perpendicular to the line being deposited, or particularly, in a direction that is non-parallel to the direction of the line. One benefit of this method is a more accurate deposition result. Traditionally, as shown in FIGS. 16A-16C, a line of material is deposited by moving the deposition head in a direction along the length of the line with a parallel motion. However, this traditional method requires that the circuit board be precisely aligned with the direction of travel of the deposition head. If a series of parallel lines is to be deposited, the distance between the nozzles must be matched to the desired distance between the parallel lines to be deposited. It is well known in the prior art to adjust the angle of the print head relative to the direction of travel to adjust the effective distance between the nozzles to an amount smaller than the actual distance between the nozzles.

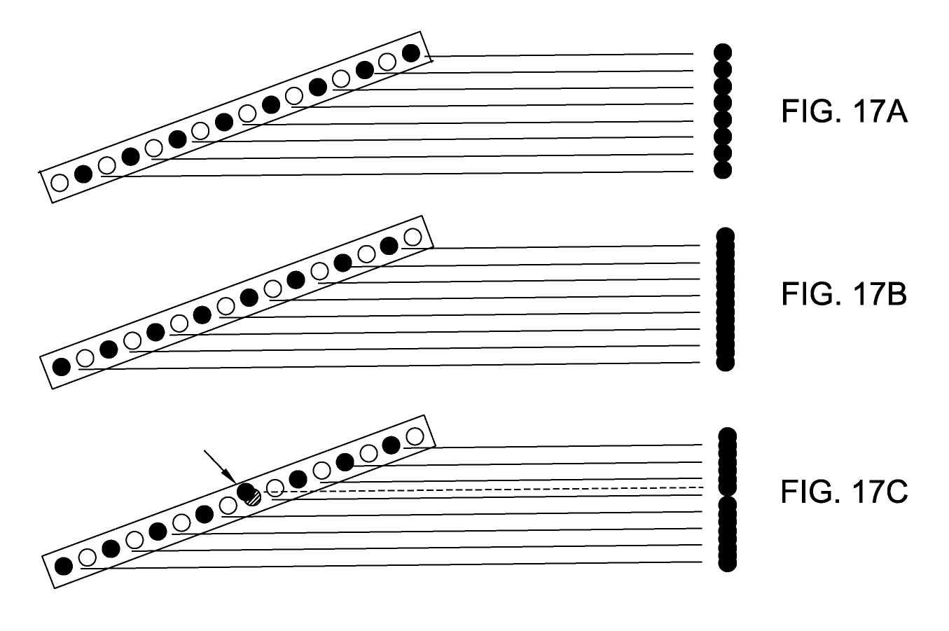

However, a series of regularly spaced nozzles is then limited to printing a series of lines with similarly regular spacing, or at least integer multiples of the set spacing by selectively using a subset of the nozzles. Furthermore, a misplaced or misaimed nozzle, as shown in FIG. 16C, will deposit a misplaced line. In contrast to this, as illustrated in FIGS. 17A-17C, and particular reference to FIG. 17C, a dot of material deposited by a misplaced or misaimed nozzle may still be deposited along the desired line. When depositing in a direction perpendicular or non-parallel to the line being deposited (the nozzle being illustrated as being non-parallel to the line being deposited in FIGS. 17A-17C), the precision of the location of the material is controlled by the firing timing of the nozzle, which can be accurately controlled by the controller. Deposit operations may be improved by advancing or retarding the timing of the firing pulses to compensate for errors in the deposition process as well as the required deposit pattern. These errors include head nozzle placement error, fluid trajectory error, and/or gantry error. Also, the advance and retardation of the firing pulses in the deposition head can be used to compensate for misalignment of the parts (substrates) to be deposited upon.

In another embodiment, an ultraviolet dye is added to the material so that the material may be made visible to the vision system having an ultraviolet light source when materials are deposited in extremely small sizes by illumination with the UV light source.

In another embodiment, the vision system may be configured for off-axis viewing of deposited materials so that wet deposits are visible without ultraviolet or infrared lighting.

In another embodiment, the deposited material is cured with one of a hot chuck, an infrared light source, and an ultraviolet light source.

In another embodiment, the deposited materials may be cooled by using one or more cooling chucks within the material deposition system. The use of cooling chucks enables the materials to solidify so that they do not bleed out expanding to a larger deposit that desired.

In another embodiment, the material deposition system may be configured to control the environment of the material deposition system, such as temperature and humidity. This environmental control allows for the use of cooling chucks without causing condensation in the material deposition system. The fan and the heating elements may be used to control the environment.

In another embodiment, the material deposition system may include an isolated space within the material deposition system to accommodate product-specific tooling for establishing a controlled temperature and humidity environment within the material deposition system. The tooling may be either configured to either heat or cool the material, and be of minimal size and directly in contact with the substrate such as to not affect other components of the material deposition system. The provision of tooling may conserve energy and lower costs.

In another embodiment, air may be removed from the flow of material within the deposition head by using gravity. Specifically, a stand tube may be provided to force the material to rise to the surface of a pool of material prior to being directed down to the nozzle of the deposition head. The stand tube is effective in separating the fluid from the entrapped air.

In another embodiment, the material deposition system may be configured to purge the deposition head with solvents to divert the material into a single waste station and the solvent-contaminated material into another waste station.

In another embodiment, a cleaning process is established within the material deposition system that utilizes added cleaning processes in a parallel processing or serial processing manner. The cleaning processes may include using one or more of the following materials or techniques, including ozone, CO₂, infrared lighting, ultraviolet lighting, plasma, or an organic solvent, such as IPA or ethanol. These materials may be used to clean the deposition head, the electronic substrate, or both.

In another embodiment, a multi-station substrate treatment may be provided within the material deposition system. For example, the multi-station substrate treatment may involve heating, cooling, or cleaning the electronic substrate, in serial or parallel processes.

In another embodiment, the deposition head can be surrounded or enveloped within a vaporous environment (potentially solvent) when static to prevent drying of the deposited material therefore maximizing the value of the material and minimize the cleaning time and waste. With this approach, the environment may be localized to the deposition head alone and not to the remaining components of the material deposition system.

In another embodiment, the control electronics are separated into two separate control boards, one associated with the deposition head (e.g., control board 164) and one associated with the gantry system. This configuration may use low level differential controlled impendence signaling to communicate without loss of signal or timing integrity.

In another embodiment, two separate cameras may be used, one associated with the deposition head and one associated with the support assembly. The camera associated with the deposition head provides a relatively small field of view and the camera associated with the support assembly provides a relatively large field of view. The small view camera has a higher magnification and a much shallower depth of focus. Thus, the small view camera must be moved in the z-axis direction to ensure the ability to focus on features that may vary in height on the electronic substrate. In one embodiment, the small view camera is mounted on the deposition head to achieve z-axis movement. The large field of view camera has a relatively large depth of focus and does not require movement in the z-axis direction. In one embodiment, the large view camera is mounted on the gantry mount assembly.

In another embodiment, the deposition head may be configured with three distinctly separate temperature controls, one control for material in cartridge, one control for material in fluid path, and one control for material in deposition head (manifold). This configuration maximizes the shelf-life of the material by only increasing the temperature of the material to the minimum amount for each stage of the distribution process.

In another embodiment, a drop watcher system can be implemented with a secondary lens/window system that is easily removable from the material deposition system to allow for easy cleaning.

In another embodiment, the material deposition system can include a noncontact head capping station. This station provides a vapor environment that prevents material from drying on the face of the nozzle plate of the jetting assembly. The capping station could be purged just prior to uncapping to keep the solvents in the material deposition system to a minimum.

In another embodiment, the substrate may be moved rather than the deposition head. Specifically, the substrate may be moved from one print position to another, allowing the material deposition system to accommodate a substrate with a length greater than the finite work area of the material deposition system. Also, for high precision applications, a substrate may be positioned by an X/Y movement stage under a fixed print head. This approach may be preferred for high accuracy applications because the geometry of an X/Y movement stage may be made to a higher level of accuracy that the geometry of a gantry system. Another embodiment may be directed to moving the substrate in one axis (e.g., in the y-axis direction), and moving the print head in another axis (e.g., in the x-axis direction).

Having thus described several aspects of at least one embodiment of this disclosure, it is to be appreciated various alterations, modifications, and improvements will readily occur to those skilled in the art. Such alterations, modifications, and improvements are intended to be part of this disclosure, and are intended to be within the spirit and scope of the invention. Accordingly, the foregoing description and drawings are by way of example only.

What is claimed is:

1. A method of depositing materials on an electronic substrate with a material deposition system of the type comprising a frame, a gantry system coupled to the frame, a deposition head coupled to the gantry system and configured to deposit dots of low viscous and semi-viscous material on the electronic substrate, and a controller configured to control the operation of the material deposition system, including the operation of the gantry system and the deposition head, the method comprising:
depositing a line or a pattern of material on the electronic substrate by moving the deposition head along an axis of motion that is substantially non-parallel to a direction of the line or pattern.

2. The method of claim 1, further comprising capturing an image of the electronic substrate with an inspection system.

3. The method of claim 2, further comprising adding an ultraviolet dye to the material prior to depositing so that the material is visible to the inspection system having an ultraviolet light source when material is deposited in extremely small sizes.

4. The method of claim 2, wherein the inspection system includes two cameras secured on the deposition head, a first camera being configured for large field of view and a second camera being configured for small field of view.

5. The method of claim 1, further comprising cooling material deposited on the electronic substrate.

6. The method of claim 5, wherein the cooling is achieved with a cooling chuck.

7. The method of claim 5, further comprising controlling the environment within the material deposition system.

8. The method of claim 7, wherein controlling the environment includes isolating an area within the material deposition system to perform a deposit operation.

9. The method of claim 1, further comprising cleaning at least one of the deposition head and the electronic substrate.

10. The method of claim 9, wherein cleaning is achieved by using one of ozone, CO₂, infrared lighting, ultraviolet lighting, plasma and organic solvent, such as IPA or ethanol.

11. The method of claim 1, further comprising surrounding the deposition head with a vaporous environment when static to prevent drying of material on the deposition head.

12. The method of claim 11, wherein surrounding the deposition head is achieved with a solvent.

13. The method of claim 1, wherein depositing material on the electronic substrate includes advancing and retarding firing pulses of the deposition head to compensate for errors in the deposit process, including deposition head placement error, material trajectory error, and gantry system error.

14. The method of claim 1, wherein depositing material on the electronic substrate includes advancing and retarding firing pulses of the deposition head to compensate for misalignment or variations of the electronic substrate.

15. A method of depositing materials on an electronic substrate with a material deposition system of the type comprising a frame, a gantry system coupled to the frame, a deposition head coupled to the gantry system and configured to deposit dots of low viscous and semi-viscous material on the electronic substrate, an inspection system configured to capture an image of the electronic substrate, and a controller configured to control the operation of the material deposition system, including the operation of the gantry system, the deposition head, and the inspection system, the method comprising:
capturing an image of the electronic substrate with the inspection system;
generating a pattern of material to be deposited on the electronic substrate with the controller; and
depositing a line or a pattern of material on the electronic substrate based on the pattern of material generated by the controller.

16. The method of claim 15, wherein the line or the pattern of material is deposited by moving the deposition head along an axis of motion that is substantially non-parallel to a direction of the line or the pattern.

17. The method of claim 15, further comprising adding an ultraviolet dye to the material prior to depositing so that the material is visible to the inspection system having an ultraviolet light source when material is deposited in extremely small sizes.

18. The method of claim 17, wherein the inspection system includes two cameras secured on the deposition head, a first camera being configured for large field of view and a second camera being configured for small field of view.

19. The method of claim 15, wherein depositing material on the electronic substrate includes advancing and retarding firing pulses of the deposition head to compensate for errors in the deposit process, including deposition head placement error, material trajectory error, and gantry system error.

20. The method of claim 15, wherein depositing material on the electronic substrate includes advancing and retarding firing pulses of the deposition head to compensate for misalignment or variations of the electronic substrate.
